(19) United States
(12) Patent Application Publication
(10) Pub. No.: US 2019/0394888 A1
(43) Pub. Date: Dec. 26, 2019

(54) PATTERNING OF ELECTROLESS METALS

(71) Applicant: AVERATEK CORPORATION, Santa Clara, CA (US)

(72) Inventors: Shinichi Iketani, Sunnyvale, CA (US); Michael Riley Vinson, Sunnyvale, CA (US)

(21) Appl. No.: 16/448,973

(22) Filed: Jun. 21, 2019

Related U.S. Application Data
(60) Provisional application No. 62/688,234, filed on Jun. 21, 2018.

(51) Int. Cl. H05K 3/46; C23C 18/16; H05K 3/42

(52) U.S. Cl. CPC H05K 3/4661; H05K 3/422; C23C 18/1603; C23C 18/1651

(57) ABSTRACT

The present invention relates to methods and systems that utilize a catalyst or thin metal film by atomic level deposition (ALD) of one or more metals that allows fine traces deposition to the trench formed in a dielectric material, thereby minimizing potential physical damage due to embedded conductor format and making the fine space between traces to prevent electromigration in the traces.

This application claims the benefit of priority to U.S. provisional application 62/688234 filed on Jun. 21, 2018. This and all other extrinsic references referenced herein are incorporated by reference in their entirety.

### FIELD OF THE INVENTION

The field of the invention is systems and methods for patterning of electroless metals on a substrate.

### BACKGROUND

The following background description includes information that may be useful in understanding the present invention. It is not an admission that any of the information provided herein is prior art or relevant to the presently claimed invention, or that any publication specifically or implicitly referenced is prior art.

Electroless metal deposition uses a redox reaction to deposit a layer of metals on a substance without the use of external electrical power. In this process, several types of metals can be used as a catalyst. For example, palladium, platinum, silver are well known catalysts for initiating electroless metal deposition on substrates. The catalysts facilitate initiation and subsequent deposition of electroless metals (e.g., copper, tin, etc.) from solutions of metal salts. The catalysts can be generated and deposited on a substrate in various forms (e.g., palladium can be deposited as colloidal palladium, ionic palladium, etc.)

Conventional fabrication of printed circuit boards uses a subtractive method of fabrication. To produce a desired copper pattern, subtractive processing uses a photolithography exposure and chemical etch to remove most of the copper that was laid down. Since the chemical etching process is isotropic, the trace shape is always a trapezoid shape and it makes a limitation for the size of space between traces.

Another conventional fabrication method of printed circuit boards uses a semi-additive method. It uses a thin conductive film for a base. A plating resist is applied over the base with a negative image of the circuitry, a metal is then plated to make enough thickness for the circuits, followed by removing the plating resist, and as a result, the thin conductor area is exposed and etched off. The less etching process for the thin base layer improves a minimum trace width. However, the adhesion of the circuitry to the base dielectric material is influenced by the roughness and/or chemical interaction between the thin base conductor and the base dielectric material. The roughness of the base dielectric material which represents the adhesion and a fine trace becomes trade off by this reason.

Many efforts have been put forth to create metal patterns using additive process. For example, a printed circuit board can be generated by creating negative plating resist pattern over a substrate surface that includes a pre-catalyzed filler, and depositing a conductor using electroless plating technique. U.S. Pat. No. 5,338,567A to Kohm teaches an example of such pre-catalyzed base material. This and all publications referenced herein are incorporated in their entirety. The fully additive conductor process prevents the fine circuitry from damage, but the pre-catalyzed base material needs a substantial amount of catalyst, which is typically made of an expensive noble metal, and becomes a potential accelerator of the electromigration. In addition, use of a pre-catalyzed base material can interfere with the dielectric constant, and can cause dissipation of the filler.

In another example, U.S. Pat. No. 5,158,860A to Gulla discloses a circuitry metalizing method for a full additive process using liquidus catalysis technique (liquid phase reaction of catalyst). This process expects removal of the absorbed catalyst over the plating resist surface, however, a possible catalyst residue ruins the result, especially in a very small feature such as very narrow space between the traces.

The following description includes information that may be useful in understanding the present invention. It is not an admission that any of the information provided herein is prior art or relevant to the presently claimed invention, or that any publication specifically or implicitly referenced is prior art.

In another example, U.S. Pat. No. 6,709,803 to Hotta discloses a potential improvement in concerns described above by applying a catalyst prior to the plating resist deposition. However, the secondary catalysis might partially form the catalyst deposition over the plating resist surface. Yet another example, U.S. Pat No. 6,884,945 to Kim teaches semi-additive process which uses electrolytic plating technique to form circuitry with plating resist. However, the base thin copper layer for the current distribution during the electrolytic plating is etched off and this process could make an undercut underneath of the circuitry which weakens its adhesion. Even the process is perfectly completed; the circuitry is still under concern of physical damaged during the manufacturing process because of three dimensionally exposed tiny circuitry features.

In some embodiments, the numbers expressing quantities of ingredients, properties such as concentration, reaction conditions, and so forth, used to describe and claim certain embodiments of the invention are to be understood as being modified in some instances by the term “about.” Accordingly, in some embodiments, the numerical parameters set forth in the written description and attached claims are approximations that can vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the invention are approximations, the numerical values set forth in the specific examples are reported as precisely as practicable. The numerical values presented in some embodiments of the invention may contain certain errors necessarily resulting from the standard deviation found in their respective testing measurements.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided with respect to certain embodiments herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member can be referred to and claimed individually or in any combination with other members of the group or other elements found herein. One or more members of a group can be included in, or deleted from, a group for reasons of convenience and/or patentability. When any such inclusion or deletion occurs, the specification is herein deemed to contain the group as modified thus fulfilling the written description of all Markush groups used in the appended claims.

Thus, there is still a need for metal patterning on substrates with new and cost effective processes that are capable of producing microscopic, functional and less expensive metal pattering.

### SUMMARY OF THE INVENTION

The inventive subject matter provides systems and methods for patterning of electroless metals. One aspect of the invention includes a method of patterning of electroless metals. One embodiment of this method includes a step of placing a catalyst layer on a substrate to make the substrate active. A dielectric material layer is then applied to a negative circuit pattern to mask the active catalyst layer. Electroless metal composition is then applied onto the exposed active catalytic layer to form a pattern of electroless metal deposition on the substrate. The electroless metal deposition is optionally further plated up (e.g., depth increase, volume increase, etc) by additional electrolytic metal deposition. Therefore, the present invention describes methods to fabricate printed circuits, by selectively exposed a conductive layer and then the metals are selectively deposited over the layer of either electroless or electroless and electrolytic plating. As used herein, “metal” means metal plated by either electroless or electrolytic deposition.

Another embodiment of this method uses a thin conductive film such as copper foil for the base material. A plating resist layer having a negative circuit pattern is placed over the base conductive base material. The exposed conductor is plated over a conductor using either electroless or electrolytic plating. Then the base conductive material is removed by either chemically or physically.

Another aspect of the invention includes a device consisting of three layers, a conductive thin film layer over a base material layer which is inactive to a plating process and a photosensitive dielectric layer is over the conductive thin film layer. This device is usable for the methods described in embodiments above.

Further methods of patterning a metal deposited by electroless plating in a multi layered circuitry are contemplated. A surface of a substrate is activated by depositing a first catalyst layer having a first catalyst material onto the substrate surface. A first dielectric material is masked onto the first catalyst layer to form a negative circuit pattern over the first catalyst layer. The negative circuit pattern image of the dielectric material is typically made by photolithography, mechanical ablation, thermal ablation, or combinations thereof. A first electroless metal is then applied onto a non-masked (e.g., exposed) portion of the first catalyst layer. In preferred embodiments, the first catalyst layer has an average thickness of less than 50 nanometers, but less than 25 nanometers, or less than 15 nanometers, are further contemplated.

The substrate typically includes at least one of a polyimide, a cloth, a plastic, a metal, a ceramic, a resin, or appropriate films thereof (e.g., polyimide film), and in preferred embodiments includes a printed circuit board. The first catalyst material includes at least one of palladium, silver, gold, nickel, copper, rhodium, cobalt, iridium, or platinum. In some embodiments, the first catalyst material is deposited as a first catalyst precursor over the substrate, which is then activated to a zero valent or nearly zero valent metal. Preferably, the first catalyst precursor includes an organo-metal, for example a metal carboxylate.

The first dielectric material is at least partially an epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin, an inorganic resin, or combinations thereof. The first dielectric material preferably, in some embodiments optimally, includes inorganic filler made of silica, glass, talc, mica, kaolin, carbonate salt, hydroxide salt, silicate salt, or combinations thereof. In some embodiments, the first dielectric material is photosensitive. The first electroless metal is typically at least one of copper, nickel, palladium, platinum, tin, silver, gold, or combinations or alloys thereof.

Further methods include depositing a second catalyst layer having a second catalyst material onto at least a portion of the first dielectric material or the first electroless metal, or both. A second dielectric material is then further deposited over the second layer of the second catalyst material. A negative hole pattern (e.g., z-axis connection) and/or circuit pattern (e.g., in z-axis, y-axis, x-axis, or whole or partial combinations thereof) is then masked onto the second catalyst layer using a second dielectric material. Alternatively or in combination, the negative hole pattern, additional hole patterns, or other circuit patterns are formed by abrasion, photolithography, or laser ablation. A second electroless metal is then deposited onto a non-masked (e.g., exposed) portion of the second catalyst layer. Additional layers of catalyst layers, dielectric masks, and electroless metals are optionally deposited in similar fashion to form a multilayer circuit. In preferred embodiments, each of the first, second, and subsequent catalyst layers independently has an average thickness of less than 50 nanometers, or less than 25 nanometers or 15 nanometers in some embodiments.

The second and any subsequent catalyst materials preferably include at least one of palladium, silver, gold, nickel, copper, rhodium, cobalt, iridium, platinum, or alloys or combinations thereof. In some embodiments, each layer of catalyst material includes a different catalyst, though layers of the same catalyst or alternating layers of the same catalyst are also contemplated.

Each of the second and any subsequent dielectric materials preferably include at least one of an epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin, an inorganic resin, or combinations thereof. The first dielectric material preferably, in some embodiments optimally, includes inorganic filler made of silica, glass, talc, mica, kaolin, carbonate salt, hydroxide salt, silicate salt, or combinations thereof. While each the dielectric materials used for each mask can be the same dielectric material (or at least partially the same), it is contemplated that each of the dielectric materials used are different, the same dielectric materials are used in an alternative fashion, or a combination of dielectric materials are used among each mask.

Each of the second and any subsequent electroless metals at least partially include at least one of copper, nickel, palladium, platinum, gold, or mixtures or alloys thereof. While each of the electroless metals deposited can be the same between each layer, or share a common metal, the metals deposited in each layer can also be different and selected based on its location in the multi layered circuitry (e.g., embedded circuitry, surface circuitry, terminal circuitry, etc.

Further methods of patterning of a metal in a multi layered circuit contemplated. A thin metal film is placed on a surface of a base material, and a first negative circuit pattern is masked on the thin metal film using a first dielectric material. A first metal is deposited onto a non-masked (e.g., exposed) portion of the thin metal film, and both the base material and the thin metal film are removed. Preferably, the first metal includes at least one of the first dielectric material or a first electroless material. In some embodiments the thin metal film has an average thickness of less than 20 micrometer.

The thin metal film preferably includes at least one of copper, silver, nickel, iron, tin, zinc, cobalt, lead, aluminum, or corresponding alloys. The base material is typically at least one of a metal, a plastic, or a ceramic. In some embodiments, the thin metal film is mechanically, chemically, or thermally removed from the base material. In some embodiments, the base material at least partially includes the same metal as the thin metal film, but the base material can also include a polyethylene terephthalate or a thermoplastic film, either alternatively or in combination.

Further methods include depositing a first catalyst layer of a first catalyst material at least partially onto the first dielectric material and the first metal. A second dielectric material is then deposited over at least part of the first catalyst layer (e.g., including part of the first catalyst material). A negative hole pattern (e.g., z-axis connection) and/or circuit pattern (e.g., in z-axis, y-axis, x-axis, or whole or partial combinations thereof) is then masked onto the first catalyst layer using the second dielectric material. Alternatively or in combination, the negative hole pattern, additional hole patterns, or other circuit patterns are formed by abrasion, photolithography, or laser ablation. A second electroless material is deposited onto a non-masked (e.g., exposed) portion of the first catalyst layer. Further multilayer circuits can be formed by depositing additional layers of catalyst, masks, and metals as described.

At least some (preferably most, more preferably all) of the first and subsequent catalyst layers include palladium, silver, gold, nickel, copper, rhodium, cobalt, iridium, platinum, or various combinations or alloys thereof.

Likewise, at least some (preferably most, more preferably all) of the first, the second, and any subsequent dielectric materials include at least one of an epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin, an inorganic resin, or combinations thereof.

Further, at least some (preferably most, more preferably all) of the first, the second, and any subsequent electroless materials include at least one of copper, nickel, palladium, platinum, tin, silver, gold, or combinations or alloys thereof.

### BRIEF DESCRIPTION OF THE DRAWINGS

FIG. 1 illustrates a flowchart of one embodiment of a method of patterning of electroless metals.

FIG. 2 illustrates a step diagram of one embodiment of a method of patterning of electroless metals.

FIG. 3 illustrates a flowchart of another embodiment of a method of patterning of metals.

FIG. 4 illustrates a step diagram of another embodiment of a method of patterning of metals.

### DETAILED DESCRIPTION

The present invention relates to methods, systems and devices for patterning metals on a substrate. One aspect of the present invention includes a method of patterning of electroless metals using electroless plating. Electroless plating uses a redox reaction to deposit metal on an object without the use of external electrical power. One of the main advantages of electroless plating is that it allows even deposition of a metal ion to all parts of the object including edges, inside of holes and irregularly shaped objects which are difficult to achieve even deposition of a metal ion by use of electrolytic plating.

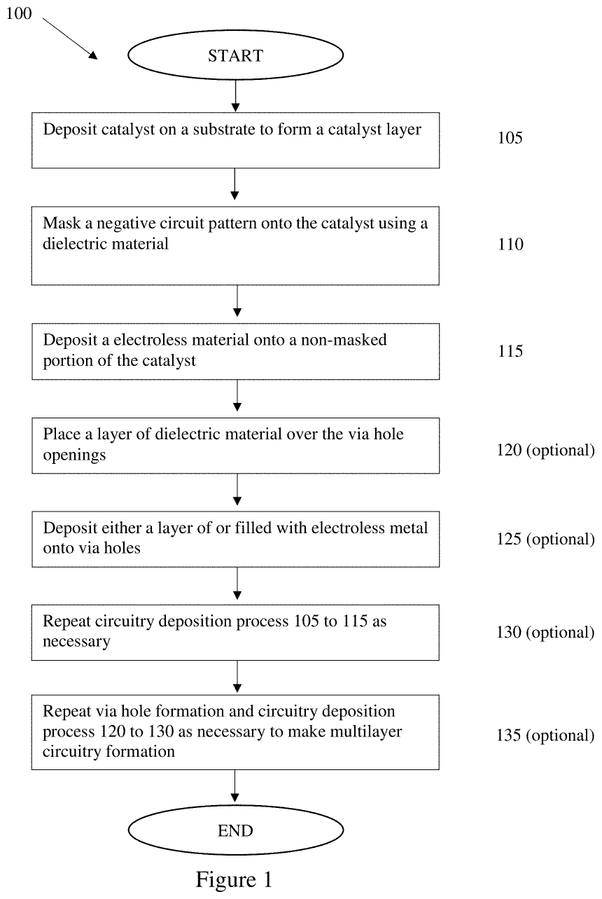

FIG. 1 illustrates one preferred embodiment of method 100 of patterning an electroless metal using electroless plating. In this embodiment, the method begins with step 105 of depositing a catalyst on the substrate to form a catalyst layer such that the substrate is at least partially coated by the catalyst layer. The substrate can be a printed circuit board and any suitable types of material, rigid or flexible, can be used as a substrate. For example, a substrate can include materials of polyimide, a cloth, a plastic, a metal, a ceramic, and a resin. It is further contemplated that many precious metals can be used as catalyst for electroless plating, including for example, palladium, gold, silver, copper, rhodium, cobalt, iridium, and platinum. Also the conductive metal such as copper that will be plated over later can be used as self catalyst.

In a preferred embodiment, the catalyst includes elemental and active metal. The active catalyst approximately has a zero valence. The active catalyst is also ideally generated or otherwise disposed as atomic-level layers onto the substrate. The thickness of the catalyst will be limited by the insulation resistance between features.

The catalyst precursor may be used to achieve thin enough catalyst layer deposition. It may be applied as a solution. For example, a palladium precursor solution can be prepared to include a Lewis base ligand and a palladium compound in a solvent. For example, in a specific embodiment, the palladium precursor solution is prepared in a form of palladium propionate (e.g., palladium (II) propionate-cyclopentylamine complex, etc.). The catalytic precursor can be an organo-metal including carbonate. Additional details on preparing a palladium propionate solution are described in the U.S. Pat. No. 8,628,818, which is incorporated herein by reference.

The catalyst precursor or a catalyst precursor solution can be delivered to a substrate in any number of different manners. For example, the catalyst precursor can be deposited without a pattern onto the substrate. A deposition involves coating a large portion or the entire substrate surface with the palladium ink. The coating method can be selected from a variety of common coating methods such as bar coating, spray coating, dip coating, roll coating, ink jet printing, offset printing and most of other common methods.

It is especially preferred that the catalyst layer has an average thickness of less than 50 nanometer, more preferably less than 25 nanometer, and most preferably less than 15 nanometer. Once the catalyst layer is placed on the substrate, the method continues with step 110 of placing a layer of patterned dielectric material on the catalyst layer. The dielectric material includes at least one of the group consisting of an epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin, and an inorganic resin.

In a preferred embodiment, the dielectric material is plated on a negative pattern of the final conductive circuitry pattern that is substantially opposite to what the final conductive circuitry pattern will be on the substrate. In some embodiments, the negative pattern is at least partially two-dimensional (X-axis and Y-axis). However, it is contemplated that the negative pattern be three dimensional (X-, Y- and Z-axis), linear (e.g., one-dimensional), or include a combination.

The negative pattern of the dielectric can be created by various printing and/or photolithography techniques. For example, conventional screen or stencil printing, and inkjet printing allows selective dielectric material deposition. Preferably, photosensitive dielectric material with ink, paste and film format used with UV or other wavelength exposure unit that allows higher density design and/or shorter process time than selective printing methods.

The other negative pattern of dielectric can be created by abrasion, laser ablasion or milling.

After the dielectric material is placed on the catalyst layer, the method continues with step 115 of placing a layer of electroless metal on the layer of patterned dielectric. Although electroless material is applied onto a catalytic layer, it cannot be deposited on the portions coated with dielectric material in the substrate, but deposited on the portions where catalytic layer is exposed. The electroless metal deposition can be used commercially available chemicals and processes, because the catalyst works well with these.

Optionally, the formed circuitry can be added another layer applying a conventional via hole formation technique. For instance, a dielectric material is deposited over the circuitry prepared substrate described in step 110. Via holes for Z-axis connections are formed in step 120 by abrasion technique with laser or mechanical drill, or by use of a photolithography technique to appropriately position the deposited dielectric material in a photolithographic image. After via hole formation, electroless metal is optionally deposited in step 125. For example, the first circuitry is made by copper, then the conventional electroless copper can be deposited over the exposed copper at via hole bottom using copper as the self-catalyst. When the via hole copper grows enough, same process cycle of optional step 130 can be used to add another circuitry. Further multilayer structure can be formed applying the same process cycle repeatedly via optional step 135. Contemplated electroless metal includes copper, nickel, palladium, platinum, tin, silver, and gold.

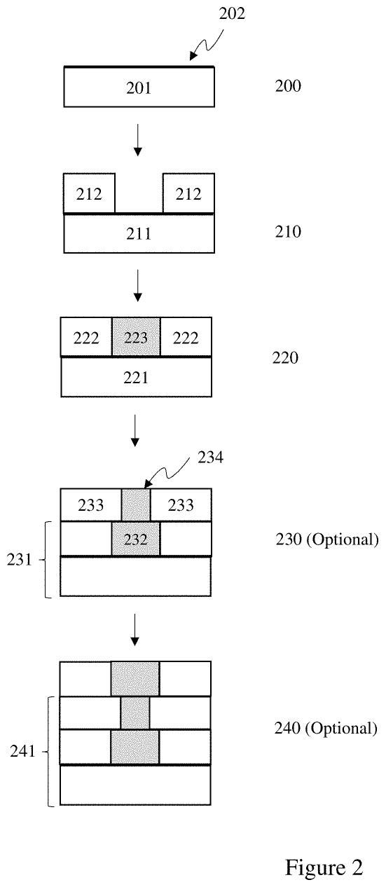

FIG. 2 illustrates a schematic diagram as cross-sectional drawing corresponding to FIG. 1 process. The first step 200 is the catalyst layer 202 preparation over the base material 201. The base material can be metal, plastic, or ceramic and also including polymers such as polyethylene terephthalate and thermoplastic film. On the prepared base material 211, a dielectric material 212 is placed over the catalyst layer with a negatively circuitry image at the step 210. Electroless metal 223 is deposited over the exposed portions of catalytic base material 221 in step 220. Because the dielectric material 222 is not active to the plating chemistry, then there is no metal deposition over the dielectric material at the step 220.

An optional step 230 makes via hole to connect two circuitry layers. As shown in step 230, dielectric material 233 is plated over the base circuitry 231 and either layered or filled metal is deposited onto a inner surface of a via hole 234, connecting to a part of base circuitry 232. The next optional step 240 is for another circuitry formation over the base 241 applying same sequence of the process from 200 to 220. The steps 230 to 240 may be repeatedly processed as necessary, and consequently the multilayer circuitry is developed.

Alternatively, instead of using the catalyst for the preliminary preparation of electroless metal deposition, a thin metal film can be applied. Appropriate thin metal films include copper, silver, nickel, iron, tin, zinc, cobalt, lead, or aluminum, but more preferably copper. A combination of these metals or an alloy can be used as well. The thin metal film can be the same as the base material. The thin metal film can be selected from workable electroless metal solution with it. The thin metal film may be settled over removable material to get enough rigidity for the process. Also thin metal film may include a sacrificial layer. Such foil is commercially available and it helps the base material removal process when it is no longer necessary. In thin metal film use for the metal deposition seed layer, it allows both electroless and electrolytic metal deposition.

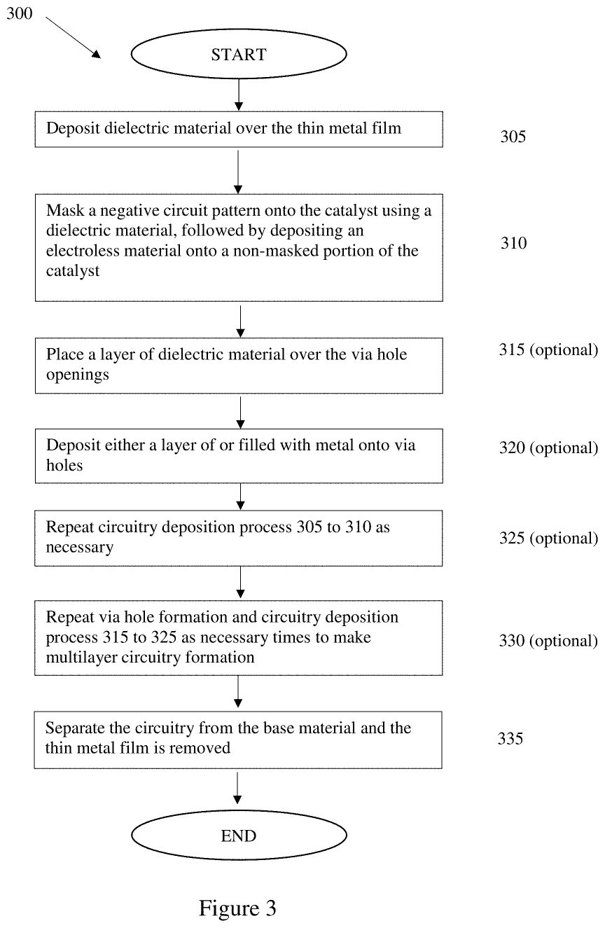

FIG. 3 illustrates another preferred embodiment of method 300 of patterning of metals using plating technique. In this embodiment, the thin metal film can be settled over a base material to get enough rigidity for the further processes (step 305). Subsequently, the dielectric material is deposited over a thin metal film on a negative pattern of the final conductive circuitry pattern (step 310). Finally, the metal layer is applied to the thin metal film layer which is not covered by the dielectric material (step 310). The metal deposition can be used either electroless or electrolytic plating.

Optionally, dielectric material with via hole openings is placed over the base circuitry in step 315. Then metal is deposited onto via hole opening in step 320. Another circuitry layer is prepared by repeating processes 305 to 310 and followed by the processes of 315 to 320, generating a multilayer circuitry design in step 330.

Lastly, the base material is removed from thin metal film and the thin metal film is removed. Then the thin metal is removed and a chemical process such as etching or physical process peeling can be used for the removal process 335.

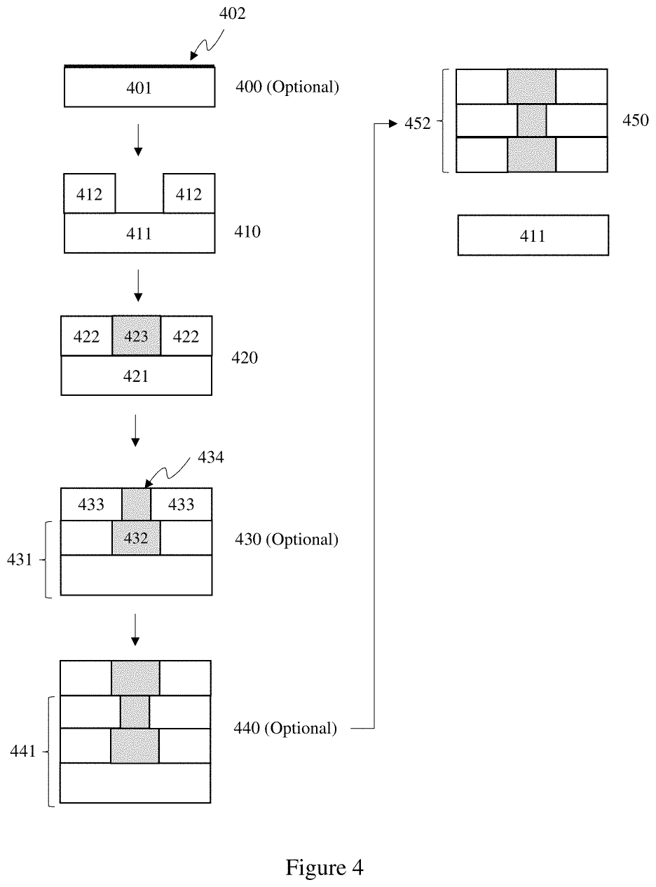

FIG. 4 illustrates a schematic diagram as cross-sectional drawing corresponding to FIG. 3. The first step 400 (optional) is the thin metal layer 402 preparation over the base material 401. On the top of the base material 410, a dielectric material 412 is placed over the thin metal film layer with negative circuitry image at the step 410. Metal 423 is deposited over the exposed thin metal layer, not covered by dielectric material, over the base material 421 in step 420.

An optional step 430 makes via hole to connect two circuitry layers. As shown in step 430, dielectric material 433 is plated over the base circuitry 431 and either layered or filled metal is deposited onto a inner layer of a via hole 434, connecting to a part of base circuitry 432. The next process 440 is for another circuitry formation over the base 441 applying same sequence of the process from 410 to 420. The steps 430 to 440 may be repeatedly processed as necessary, and consequently the multilayer circuitry is developed. Optional step 450 depicts the removal of base material 401 and thin metal layer 402 (collectively 411) forming circuitry 452.

The discussion herein provides example embodiments of the inventive subject matter. Although each embodiment represents a single combination of inventive elements, the inventive subject matter is considered to include all possible combinations of the disclosed elements. Thus if one embodiment comprises elements A, B, and C, and an intermediate embodiment comprises elements B and D, then the inventive subject matter is also considered to include other remaining combinations of A, B, C, or D, even if not explicitly disclosed

As used herein, and unless the context dictates otherwise, the term “coupled to” is intended to include both direct coupling (in which two elements that are coupled to each other contact each other) and indirect coupling (in which at least one additional element is located between the two elements). Therefore, the terms “coupled to” and “coupled with” are used synonymously.

Unless the context dictates the contrary, all ranges set forth herein should be interpreted as being inclusive of their endpoints, and open-ended ranges should be interpreted to include commercially practical values. Similarly, all lists of values should be considered as inclusive of intermediate values unless the context indicates the contrary.

It should be apparent to those skilled in the art that many more modifications besides those already described are possible without departing from the inventive concepts herein. The inventive subject matter, therefore, is not to be restricted except in the scope of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Where the specification claims refers to at least one of something selected from the group consisting of A, B, C . . . and N, the text should be interpreted as requiring only one element from the group, not A plus N, or B plus N, etc.

What is claimed is:

1. A method of patterning of a metal deposited by electroless plating in a multi layered circuitry comprising:
activating a surface of a substrate by depositing a first catalyst layer comprising a first catalyst material;
masking a first negative circuit pattern on the first catalyst layer using a first dielectric material;
applying a first electroless metal onto a non-masked portion of the first catalyst layer; and
wherein the first catalyst layer has an average thickness of less than 50 nanometers.

2. The method of claim 1, wherein the substrate comprises at least one of the group consisting of a polyimide, a film, a cloth, a plastic, a metal, a ceramic, and a resin.

3. The method of claim 1, wherein the substrate comprises a printed circuit board.

4. The method of claim 1, wherein the first catalyst material comprises at least one of the group consisting of palladium, silver, gold, nickel, copper, rhodium, cobalt, iridium, and platinum.

5. The method of claim 1, wherein the first catalyst material is deposited as a first catalyst precursor over the substrate and then is activated to an almost zero valent metal.

6. The method of claim 5, wherein the first catalyst precursor comprises an organo-metal.

7. The method of claim 6, wherein the organo-metal comprises a metal carboxylate.

8. The method of claim 1, wherein the first catalyst layer has an average thickness of less than 25 nanometers.

9. The method of claim 1, wherein the first catalyst layer has an average thickness of less than 15 nanometers of the catalyst.

10. The method of claim 1, wherein the first dielectric material comprises at least one of the group consisting of an epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin and an inorganic resin.

11. The method of claim 1, wherein the first dielectric material is photosensitive.

12. The method of claim 1, wherein the first electroless metal comprises at least one of the group consisting of copper, nickel, palladium, platinum, tin, silver, and gold.

13. The method of claim 1, further comprising:
a) depositing a second catalyst layer comprising a second catalyst material onto each the first dielectric material and the first electroless metal;
b) depositing a second dielectric material over the second layer of the second catalyst material;
c) masking a second negative pattern (optionally including a z-axis connection) onto the second catalyst layer using a second dielectric material;
d) depositing a second electroless metal onto a non-masked portion of the second catalyst layer; and
e) optionally repeating the method from step (a) to step (d), thereby generating a multilayer circuit, wherein each of the first, second and any subsequent catalyst layers independently has an average thickness of less than 50 nanometers.

14. The method of claim 13, wherein each of the second and subsequent catalyst materials independently comprises at least one of the group consisting of palladium, silver, gold, nickel, copper, rhodium, cobalt, iridium, and platinum.

15. The method of claim 13, wherein each of the second and subsequent dielectric materials independently comprises at least one of the group consisting of an epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin and an inorganic resin.

16. The method of claim 13, wherein each of the second and any subsequent electroless metals comprises at least one of the group consisting of copper, nickel, palladium, platinum, and gold.

17. The method of claim 13, wherein the negative hole pattern is formed by photolithography or abrasion.

18. A method of patterning a metal in a multi layered circuit, the method comprising:
placing a thin metal film on a surface of a base material;
masking a first negative circuit pattern on the thin metal film using a first dielectric material;
depositing a first metal onto a non-masked portion of the thin metal film; and
removing both the base material and the thin metal film;
wherein the first metal comprises at least one of the group consisting of the first dielectric material and a first electroless material; and
wherein the thin metal film has an average thickness of less than 20 micrometer.

19. The method of claim 18, wherein the thin metal film is at least one of the group consisting of copper, silver, nickel, iron, tin, zinc, cobalt, lead, aluminum, and corresponding alloys.

20. The method of claim 18, wherein the base material comprises from metal, plastic or ceramic.

21. The method of claim 18, wherein the thin metal film is mechanically or chemically removed from the base material.

22. The method of claim 18, wherein the base material comprises the same metal as the thin metal film.

23. The method of claim 18, wherein the base material comprises a polyethylene terephthalate or a thermoplastic film.

24. The method of claim 18, further comprising:
a) depositing a first catalyst layer of a first catalyst material onto the first dielectric material and the first metal;
b) depositing a second dielectric material over the first layer of the catalyst material;
c) masking a negative hole pattern (z-axis connection) onto the first catalyst layer using the second dielectric material;
d) depositing a second electroless material onto a non-masked portion of the first catalyst layer;
e) optionally repeating the method from step (a) to step (d), thereby generating a multilayer circuit.

25. The method of claim 24, wherein each of the first and any subsequent catalyst layers comprises at least one of the group consisting of palladium, silver, gold, nickel, copper, rhodium, cobalt, iridium and platinum.

26. The method of claim 18, wherein each of the first, the second and subsequent dielectric materials comprises at least one of the group consisting of a epoxy resin, a cyanate ester resin, a polyphenylene ester resin, a polyimide resin, a bismaleimide trianzine resin, a polyethylene terephthalate resin, a hydrocarbon resin, a polyfluoro carbon, a LCP resin, and an inorganic resin.

27. The method of claim 18, wherein each of the first, the second and subsequent electroless materials comprises at least one of the group consisting of copper, nickel, palladium, platinum, tin, silver, and gold.

28. The method of claim 24, wherein the negative hole pattern is formed by photolithography or abrasion.
